(19) United States
(12) Patent Application Publication
(10) Pub. No.: US 2009/0132242 A1
(43) Pub. Date: May 21, 2009

(54) PORTABLE AUDIO RECORDING AND PLAYBACK SYSTEM

(75) Inventors: Wei-Sheng WANG, Kaohsiung City (TW); Cheng-Wen TSAI, Kaohsiung City (TW); Szu-Hsuan WANG, Kaohsiung City (TW); Chun-Chang CHANG, Kaohsiung City (TW)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignee: COOL-IDEA TECHNOLOGY CORP., Kaohsiung City (TW)

(21) Appl. No.: 11/942,209

(22) Filed: Nov. 19, 2007

(51) Int. Cl. H03G 3/20; G10L 19/00; H04R 1/00

(52) U.S. Cl. 704/216; 381/61; 381/150; 381/107; 381/63; 704/E19.001

(57) ABSTRACT

A portable audio recording and playback system is provided. The portable audio recording and playback system can synchronously display the corresponding lyrics or character contents, and it also can selectively record user's voice or the mixed signal of the user's voice and a background music including music and a human voice of singer during playback. Or the volume of the human voice in the background music can be increased or decreased corresponding to that of the music and be outputted or repeatedly played with changing speech speed without the tone changed for achieving the effects of on-the-go vocal and/or music accompaniment, voice recording, and language learning with changing speech speed without the tone changed.

### BACKGROUND OF THE INVENTION

1. Field of the Invention

This invention relates to a portable audio recording and playback system and more particularly to a system that is applied to an electronic device synchronously displaying lyrics or characters when a background music including music and a human voice of singer is being played, and recording voice of user, after which the background music mixed with the voice or only the voice and the lyrics are synchronously outputted or the volume of the human voice of singer corresponding to that of the music can be increased or decreased and then be outputted or repeatedly played with changing speech speed without the tone changed.

2. Description of Related Art

Currently, the music player of an MP3 (MPEG Audio Layer 3) flash drive and other hand-held electronic products may function to store data and play back music in MP3 format and even may support lyrics display of MP3 files.

The electronic device provided with the MP3 playback function may not only play music but also involve teaching so that a user may learn foreign languages by listening to MP3 songs or programs in foreign languages; indeed, it is an edutainment way of learning foreign languages, so that the user can learn foreign languages by osmosis. Thus, using the electronic device is a good way of learning. However, the functions of the electronic device may only improve the learner's capability in listening and reading comprehension but may not instruct the user how to pronounce and may not correct his or her accent; namely, user's voice can not be recorded during music playback and lyrics display at the time of playback; therefore, the user is unable to verify whether his/her voice or accent is correct by listening to the recorded voice or accent repeatedly. In addition, when the user listens to foreign songs or teaching materials, if the user wants to rewind to a certain point of the file for repeat play, the conventional MP3 flash drive music player is unable to rewind to the certain point of the file as a tape does during work. Although the MP3 flash drive music player may provide a feature of fixed-point repeat playback, the oral speech given from the file is still too fast, such that the user is unable to listen clearly, thereby reducing the user's will of learning in listening comprehension.

Further, modern people increasingly pay much attention to recreation, in which singing is one of the most popular activities; however, for singing, most people must go to a specific site providing karaoke equipment, and the site for singing may be a karaoke bar, a karaoke box, and a pickup truck in which a movable karaoke device is installed. Regardless of the sites mentioned above, microphones are limited in amount, and especially when many persons enjoy singing, each of them has to wait long time to sing in turn. Although a service of sound or video recording is provided for customers in very few locations, it is too expensive for a customer to accept.

For this reason, in consideration of improvability of the defects described above, the inventor expects to provide an audio recording and playback system provided with the functions of language learning and on-the-go karaoke of music and lyrics for language learners, people who enjoy singing, and public consumers.

Consequently, because of the technical defects of described above, the applicant keeps on carving unflaggingly through wholehearted experience and research to develop the present invention, which can effectively improve the defects described above.

### SUMMARY OF THE INVENTION

In order to solve the problems and defects described above, one object of this invention is to provide a portable audio recording and playback system. When background music and its lyrics are played and displayed synchronously, user's voice or the mixed signal of the background music and the user's voice may be recorded, and after recording, the background music and its lyrics and the recorded user's voice are played synchronously for the purpose of on-the-go vocal accompaniment and recording.

Another object of this invention is to provide a portable audio recording and playback system. When background music and its lyrics are played and displayed synchronously, user's voice or the mixed signal of the background music and user's voice may be recorded, and after recording, the background music and its lyrics and the recorded user's voice are played synchronously for the purpose of pronunciation and accent correction.

Further object of this invention is to provide a portable audio recording and playback system. When voice and texts of teaching materials are played and displayed synchronously, user's voice is recorded, and after recording, only the user's voice is played back for the purpose of pronunciation and accent correction.

Yet another object of this invention is to provide a portable audio recording and playback system. Upon a user's demand, voice of teaching materials can be played from a certain point with changing speech speed without the tone changed for training the capability of “listening comprehension”, thereby increasing the user's will of language learning.

Thus, for the objects mentioned above, the system comprises: a memory device used to pre-store a digital music signal and a character content; a decoding and sound effect processing unit used to process the digital music signal for a special effect and to decode it into an analog music signal; a voice input unit used to input an analog voice signal; a mixing device used to mix the analog music signal with the analog voice signal inputted from the voice input unit for outputting analog sound effect signals; an encoding unit used to encode an analog sound effect signal into a digital audio signal that will be stored in the memory unit; a display unit used to display the character content; a control unit used for controlling the reading of the digital audio signal and the character content and integrating them into the memory device; and an audio output unit used to output the digital audio signal, wherein the control unit controls the digital audio signal to be outputted to the audio output unit, and meanwhile controls the character content from the memory device to be displayed/shown on the display unit for synchronization of music with lyrics, and the digital audio signal controlled by the control unit may be outputted beginning from a pre-defined time of the corresponding indexed data or time data, and works synchronously with the character content to be shown on the display unit. Therefore, the objects of vocal and/or music accompaniment, voice recording, recorded sound effect playback and synchronous character content display, recorded voice playback and synchronous character content display, and repeated playback for language learning hereby may be accomplished.

Besides, the analog voice signal may be alone encoded by the encoding unit into the digital voice signal and then be stored in the memory unit, while the control unit further reads the digital voice signal to output the signal from the audio output unit, thereby achieving the functions of the recorded voice playback and the pronunciation and accent correction for language learning.

In order to further understand the features and technical means of this invention, refer to the detailed description below according to this invention accompanied with drawings; however, the accompanied drawings are provided for reference and illustration only and are not limited to this invention.

### BRIEF DESCRIPTION OF THE DRAWINGS

FIG. 1 is a block diagram illustrating the structure of the present invention.

### DETAILED DESCRIPTION OF THE PREFERRED EMBODIMENTS

The present invention will be described more specifically with reference to the following embodiments. It is to be noted that the following descriptions of preferred embodiments of this invention are presented herein for purpose of illustration and description only; it is not intended to be exhaustive or to be limited to the precise form disclosed.

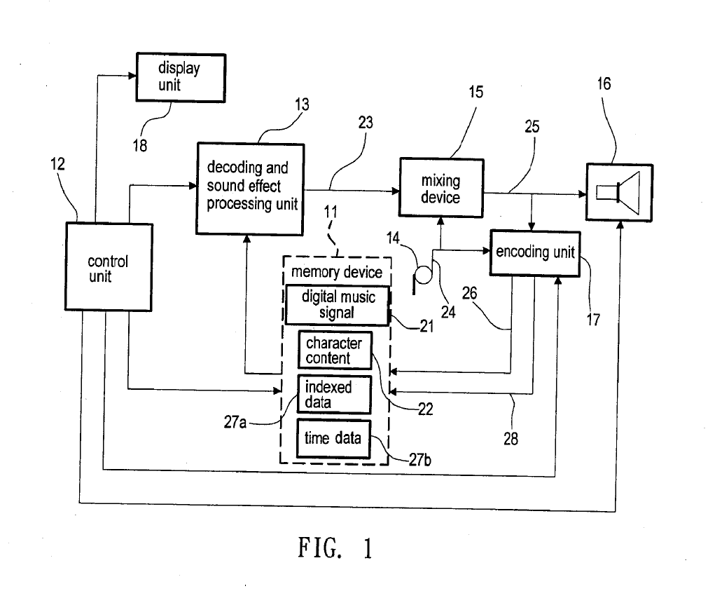

With reference to FIG. 1, a portable audio recording and playback system according to this invention comprises a memory device 11, a control unit 12, a decoding and sound effect processing unit 13, a voice input unit 14, a mixing device 15, an audio output unit 16, an encoding unit 17, and a display unit 18.

In FIG. 1, the memory device 11 in which data may be stored is an accessible memory, storing what a user wants to record. The recorded contents may be a digital music signal 21 and a character content 22; for example, the recorded contents may be voice and texts of teaching materials or music and lyrics for vocal accompaniment, both of which are provided with corresponding indexed data 27a or time data 27b for synchronous output; the recorded format may be in a digital format, such as MP3 or the like, and can be transmitted to a PC via a Universal Serial Bus (USB).

The decoding and sound effect processing unit 13 functions to decode a digital signal into an analog signal and perform a sound effect process. The function of the sound effect process is to adjust the frequencies or amplitudes of signals, namely keying up or down a tone of music, or to fix the frequencies and amplitudes of signals while speeding up or down the signal output, so as to achieve a function of changing speech speed without the tone changed may be achieved; alternatively, the left channel or the right channel of the digital audio signal may be outputted alone; moreover, the volume of the human voice in a background music of the digital music signal 21 stored in the memory device 11 may be increased or decreased corresponding to that of the music in the background music by the decoding and sound effect processing unit 13, and then is outputted to the audio output unit 16. An analog voice signal 24 is inputted from the voice input unit 14 and then outputted to the mixing device 15 and the encoding unit 17.

The mixing device 15 works to mix the analog music signal 23 outputted by the decoding and sound effect processing unit 13 with the analog voice signal 24 inputted by the voice input unit 14, and to output an analog sound effect signal 25. The encoding unit 17 works to encode the analog sound effect signal 25 into a digital audio signal 26 and store it in a format of MP3 (as an example hereinafter), OGG, or FLAC in the memory device 11.

The voice input unit 14 is generally a voice receiving device provided with a built-in microphone, an external microphone, or plural microphone sets; some of the microphones are featured with an echo effect to enhance a sound effect of vocal accompaniment. The voice input unit 14 may receive an external voice signal; the audio output unit 16 may be a speaker or a set of earphones, depending on a user's demand or an application condition.

The memory device 11, the decoding and sound effect processing unit 13, the encoding unit 17, and the display unit 18 are connected to the control unit 12, meaning that the control unit 12 is a key unit for control. The portable audio recording and playback system according to this invention comprises the functions of vocal and/or music accompaniment, user's voice recording, recorded audio signal playback and synchronous character content display, and recorded voice playback only, and all of the functions are controlled by the control unit 12.

When the user chooses the function of vocal and/or music accompaniment, the control unit 12 controls the decoding and sound effect processing unit 13 to read the pre-recorded digital music signal 21 in the memory device 11 and decodes it into the analog music signal 23; if the user further chooses to key up or down the tone, the decoding and sound effect processing unit 13 will then process the sound effect. Here, the analog music signal 23 may be outputted by the audio output unit 16; meanwhile, the control unit 12 reads the indexed data 27a or time data 27b that is corresponding to the character content 22 stored in the memory device 11 and synchronously outputs the character content 22 with the analog music signal 23 to the display unit 18, thereby achieving the function of vocal and/or music accompaniment as karaoke. And at this time, if the user chooses to record himself/herself voice, the analog voice signal 24 is inputted from the voice input unit 14, and then the mixing device 15 mixes the analog voice signal 24 with the analog music signal 23 into the analog sound effect signal 25, and the analog sound effect signal 25 is encoded by the encoding unit 17 into the digital audio signal 26 in the format of MP3 and stored in the memory device 11. Thus, the background music and the user's voice may be mixed and recorded at the same time, so that the control unit 12 can read the audio signal mixing the background music with the voice from the memory device 11 and output it to the audio output unit 16, so as to achieve parallel playback of the background music and voice and synchronous display of the character content 22 on the display unit 18. Other than the above described functions, the user may choose to output the background music and the recorded user's voice in either the left channel or the right channel alone, or alternatively the volume of the human voice in the background music may be decreased to highlight the music. Wherein the above mentioned music indicates music sound only and the voice indicates the voice sound of user; in addition, the background music includes the music and/or a human voice of singer. More specifically, the human voice of singer in the background music is differed from the voice of user.

Alternatively, the analog voice signal 24 is encoded directly by the encoding unit 17 into the digital voice signal 28 in the format of MP3, and in the meantime the indexed data 27a or time data 27b that is corresponding to the character content 22 recorded in the memory device 11 are generated and stored in the memory device 11. When the user chooses to play back the recorded voice and have the character content 22 shown, the control unit 12 reads the character content 22 from the memory device 11 with its corresponding digital voice signal 28; the character content 22 is displayed on the display unit 18, and the digital voice signal 28 and its corresponding character content 22 are synchronously outputted to the audio output unit 16 and the display unit 18, thereby achieving the objects of recording, playback, and synchronous display of characters according to this invention.

Alternatively, the analog voice signal 24 is directly encoded by the encoding unit 17 into the digital voice signal 28 in the format of MP3 stored in the memory device 11. When the user chooses to play back only the recorded voice, the control unit 12 reads the digital voice signal 28 from the memory device 11 and the digital voice signal 28 is directly outputted to the audio output unit 16, so as to achieving the objects of recording and recorded voice playback only. Therefore, users may use this invention as a small “personal recording studio” to record himself/herself singing.

Further, the memory device 11 stores the indexed data 27a or time data 27b that is corresponding to the digital music signal 21 and the character content 22 respectively. Therefore, as long as finding corresponding segments of the indexed data 27a or time data 27b, chorus of the background music, sections of the background music required for more practice, or favorite sections of the background music are repeated, such that the user does not have to wait from the beginning of a song, saving the user's practice time or wait time and reaching an effect of on-the-go vocal and/or music accompaniment.

On the other hand, this invention may also be provided for learning languages. The user may store teaching materials' recorded voice data and corresponding character contents in the memory device 11, and also must store the indexed data 27a or the time data 27b (processed by a PC and thus not described in detail therein) that is corresponding to the recorded voice data and the character content, and then the user may listen to the recorded voice data and read the character content depending on the manner or flow described above. Next, a benefit of the invention for learning languages focuses on the function of partially repeated listening. Therefore, if carelessly missing a section or planning to repeat a section where the user wants to listen to, by controlling a data segment of the indexed data 27a or time data 27b that is corresponding to the section as an initial index or an initial time, and then starting from the initial index or the initial time, the user may repeatedly listen to what s/he want, so that the user does not have to listen from the default initial point of the recorded voice data file every time, not only saving the user's time but also making the user get more done in less time.

Next, the decoding and sound effect processing unit 13 according to this invention is provided with the function of sound effect processing “at changing speech speed without the tone changed”, thus it may help the language learner adjust the speed of spoken language. If a beginner use it, s/he may adjust the speed of playback of the teaching material's recorded voice data to a lower speed so as to clearly listen to the pronunciation and accent of each word, and then may adjust the speed of playback to a higher speed in proper sequence to practice oral language at a normal speed, thereby achieving the training of “listening comprehension” and increasing the will of language learning with changing speech speed without the tone changed.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A portable audio recording and playback system, comprising
a memory device used to pre-store a digital music signal and at least a character content, wherein the digital music signal and the character content are provided with corresponding indexed data or time data;
a decoding and sound effect processing unit used to process the digital music signal for a special effect and to decode it into an analog music signal;
a voice input unit used to input an analog voice signal;
a mixing device used to mix the analog music signal with the analog voice signal inputted from the voice input unit for outputting an analog sound effect signal;
an encoding unit used to encode the analog sound effect signal into a digital audio signal stored in the memory unit;
a display unit displaying the character content;
a control unit controlling reading of the digital audio signal and the character content and integrating the digital audio signal and the character content into the memory device; and
an audio output unit used to output the digital audio signal;
wherein the control unit controlling the digital audio signal outputted to the audio output unit and meanwhile controlling the character content displayed on the display unit, and using the corresponding indexed data or time data for synchronization of music with lyrics; the decoding and sound effect processing unit being capable of keying a tone of the analog music signal.

2. The system according to claim 1, wherein the decoding and sound effect processing unit further changes an output speed of the digital audio signal without tone changed.

3. The system according to claim 1, wherein the encoding unit adopts a format selected from a group of MP3, OGG, and FLAC.

4. The system according to claim 1, wherein the analog voice signal is alone encoded by the encoding unit into a digital voice signal stored in the memory unit and the control unit further reads and directly outputs the digital voice signal to the audio output unit.

5. The system according to claim 1, wherein the control unit further integrates the digital music signal with the character content, the digital music signal is directly outputted by the audio output unit, and the character content and the digital music signal are synchronously displayed on the display device.

6. The system according to claim 1, wherein the audio output unit is a speaker or a set of earphones.

7. The system according to claim 1, wherein the voice input unit is a built-in microphone.

8. The system according to claim 1, wherein the voice input unit is an external microphone

9. The system according to claim 1, wherein the voice input unit is plural microphone sets.

10. The system according to claim 1, wherein the digital audio signal is controlled by the control unit and outputted beginning from a pre-defined time of the corresponding indexed data or time data, and works synchronously with the character content.

11. The system according to claim 1, wherein the decoding and sound effect processing unit outputs alone either a left channel or a right channel of the digital audio signal.

12. The system according to claim 1, wherein the decoding and sound effect processing unit increases or decreases a volume of human voice of the digital music signal stored in the memory device with respect to that of music of the digital music signal, and the human voice is outputted by the audio output unit.

13. The system according to claim 1, wherein the voice input unit is provided with a device featured with an echo effect.
